(19) United States
(12) Patent Application Publication
(10) Pub. No.: US 2010/0103596 A1
(43) Pub. Date: Apr. 29, 2010

(54) ROTATION MODULE AND ELECTRONIC DEVICE USING THE SAME

(75) Inventor: FAN ZHOU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/494,535

(22) Filed: Jun. 30, 2009

(30) Foreign Application Priority Data
Oct. 24, 2008 (CN) 200810305190.2

(51) Int. Cl. H05K 5/00; F16C 17/04

(52) U.S. Cl. 361/679.01; 384/420

(57) ABSTRACT

A rotation module includes a base and a rotation member. The base includes a resisting end and a connecting end opposite to the resisting end. A periphery of the resisting end forms a curved surface. The rotation member is rotatably positioned on the base. The rotation member includes a bottom surface and a supporting surface opposite to the bottom surface. The rotation member defines a circular depression for receiving the resisting end in the bottom surface. The depression has a circular slanted sidewall resisting the curved surface.

### BACKGROUND

1. Technical Field

The present disclosure relates to a rotation module and an electronic device using the same.

2. Description of the Related Art

A common electronic device includes a main body, a cover, and a rotation module connecting the cover to the main body. The rotation module includes a base, a frictional washer, a rotating plate, a connecting member, and a fastener. The frictional washer and the rotating plate are positioned on the base. The connecting member passes through the base, the frictional washer, and the rotation member, finally engaging the fastener, such that the rotating plate is rotatable relative to the base. The cover is attached to the rotating plate, and the base is fixed on the main body, thus the cover is rotatable relative to the main body.

However, with use, the components experience wear, causing the rotating plate and the cover to rotate without restriction.

Therefore, a rotation module and an electronic device using the same are desirable in order to overcome the described limitations.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an embodiment of an electronic device including an embodiment of a rotation module.

FIG. 2 is an exploded, isometric view of the rotation module applied in the electronic device.

FIG. 3 is a cross-section of the rotation module in FIG. 2 after assembly.

### DETAILED DESCRIPTION

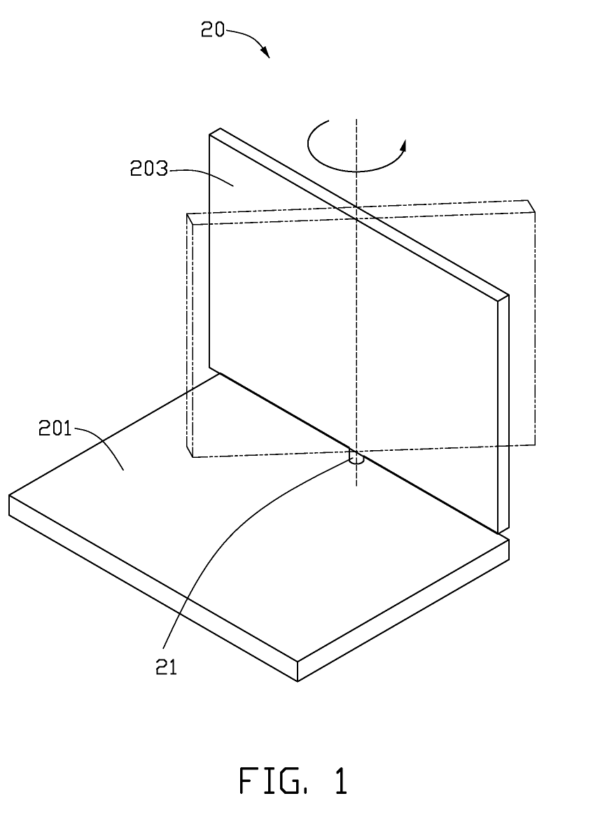

Referring to FIG. 1, an electronic device 20 includes a main body 201, a cover 203, and a rotation module 21 connecting the main body 201 to the cover 203.

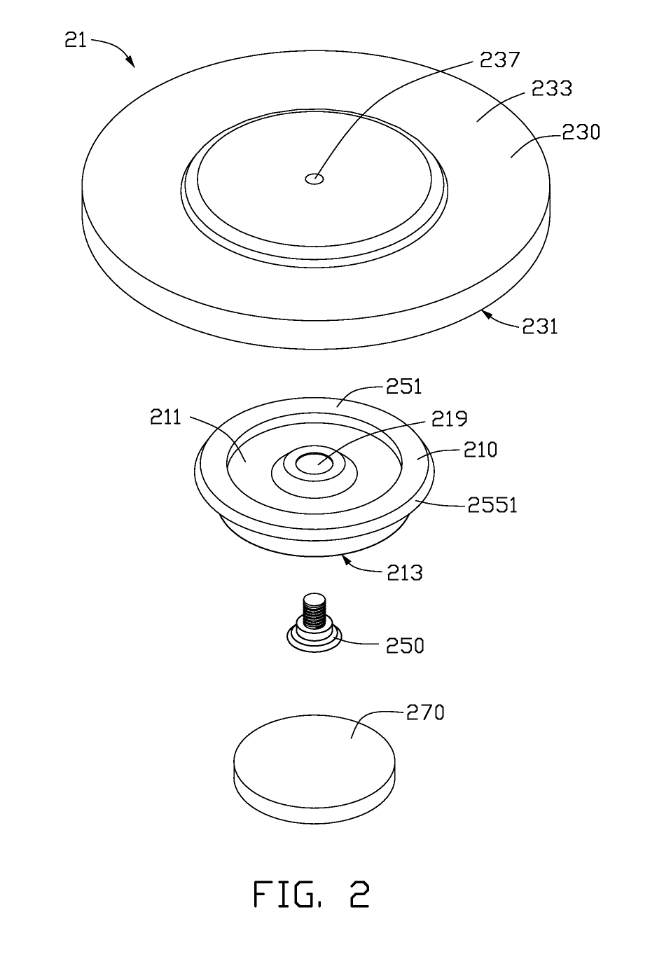

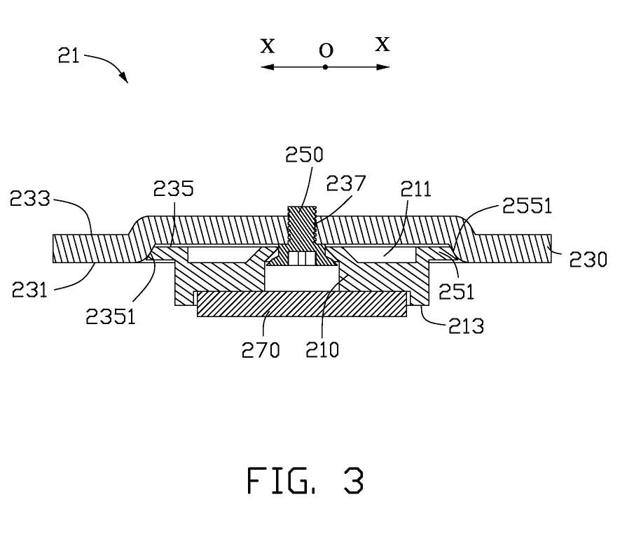

Also referring to FIGS. 2 and 3, the rotation module 21 includes a base 210, a rotation member 230 positioned on the base 210, a fixing member 250 connecting the base 210 to the rotation member 230, and a buffer washer 270.

The base 210 may be a substantially circular plate and includes a resisting end 211 and a connecting end 213 opposite to the resisting end 211. A substantially ring-shaped protrusion 251 is formed on a periphery of the resisting end 211. The ring-shaped protrusion 251 is elastic. An end of the ring-shaped protrusion 251 forms a substantially curved surface 2551. A surface roughness of the curved surface 2551 may be 3.2 microns (μm) to 12.8 μm, determined by the arithmetic average roughness (Ra). The connecting end 213 defines a receiving depression (not labeled) receiving a portion of the buffer washer 270. In addition, the base 210 further defines a through hole 219 through the connecting end 213 in a central portion of the base 210.

The rotation member 230 may be substantially plate-shaped and includes a bottom surface 231 and a supporting surface 233 opposite to the bottom surface 231. The bottom surface 231 defines a circular depression 235 receiving the resisting end 211 of the base 210. The depression 235 has a circular slanted sidewall 2351 to engage the curved surface 2551. A surface roughness of the slanted sidewall 2351 may be 3.2 μm to 12.8 μm, determined by the arithmetic average roughness (Ra). The rotation member 230 defines a locking hole 237 extending through the bottom surface 231 and the supporting surface 233 in a central portion of the rotation member 230.

The fixing member 250 connects the base 210 to the rotation member 230. In the illustrated embodiment, the fixing member 250 is a nut.

The buffer washer 270 may be made of plastic, and a bottom surface (not labeled) of the buffer washer 270 may form a plurality of micro-protrusions (not shown).

When assembling the electronic device 20, the curved surface 2551 of the base 210 resists the slanted sidewall 2351 of the depression 235, an end of the fixing member 250 passes through the through hole 219 of the base 210 and engages the locking hole 237 of the rotation member 230 such that the rotation member 230 is rotatably positioned on the base 210. The buffer washer 270 is received in the receiving depression of the base 210. The connecting end 213 of the base 210 is fixed on the main body 201, and the cover 203 is attached to the supporting surface 233 of the rotation member 230, thus yielding the electronic device 20.

The curved surface 2551 supports the rotation member 230 as the rotation member 230 and the base 210 constrain each other. When the rotation member 230 rotates relative to the base 210, the cover 203 rotates relative to the main body 201. Furthermore, when the rotation member 230 rotates, sliding friction is created between the base 210 and the rotation member 230 as the curved surface 2551 resists the slanted sidewall 2351. The rotation member 230 can remain in any desired position relative to the base 210 due to friction.

If the rotation member 230 or the base 210 is abraded, the curved surface 2551 could still resist the slanted sidewall 2351 because of the weight of the rotation member 230. This ensures that the curved surface 2551 and the slanted sidewall 2351 are always in contact with each other, preventing the rotation member 230 from wavering along any direction X. Additionally, the protrusion 251 ensures and maintains contact with the rotation member 230 because there is an elastic restoring force stored in the protrusion 251.

A depth of the depression 235 of the bottom surface 231 may be increased with an increased height of the ring-shaped protrusion 251, such that the mechanical reliability of the rotation module 21 is enhanced. In addition, the ring-shaped protrusion 251 is a substantially hollow structure, reducing the weight of the base 210 and the rotation module 21.

It can be understood that the buffer washer 270 being plastic, can absorb external shocks to protect the base 210 and the rotation member 230. Alternatively, the buffer washer 270 may be omitted, with the rotation member 230 integrally formed with the cover 203, and the base 210 integrally formed with the main body 201. The base 210 may be positioned on the rotation member 230.

Finally, while various embodiments have been described and illustrated, the embodiments are not to be construed as being limited thereto. Various modifications can be made to the embodiments by those skilled in the art without departing from the true spirit and scope of the embodiments as defined by the appended claims.

What is claimed is:

1. A rotation module comprising:
a base comprising a resisting end and a connecting end opposite to the resisting end, wherein a periphery of the resisting end forms a curved surface; and
a rotation member rotatably positioned on the base, the rotation member comprising a bottom surface and a supporting surface opposite to the bottom surface, the rotation member defining a circular depression to receive the resisting end in the bottom surface, the depression having a circular slanted sidewall resisting the curved surface.

2. The rotation module of claim 1, wherein a periphery of the resisting end forms a ring-shaped protrusion; the curved surface is formed on an outer side of an end of the ring-shaped protrusion.

3. The rotation module of claim 2, wherein the ring-shaped protrusion is elastic.

4. The rotation module of claim 1, wherein a surface roughness of the curved surface is 3.2 μm to 12.8 μm, determined by the arithmetic average roughness (Ra).

5. The rotation module of claim 1, wherein a surface roughness of the slanted sidewall is 3.2 μm to 12.8 μm, determined by the arithmetic average roughness (Ra).

6. The rotation module of claim 1, further comprising a fixing member, wherein the base defines a through hole, the rotation member defines a locking hole, and the fixing member passes through the through hole and engages the locking hole.

7. The rotation module of claim 6, wherein the fixing member is a nut.

8. The rotation module of claim 1, further comprising a buffer washer, wherein the base defines a receiving depression in the bottom surface of the base, and a portion of the buffer washer is received in the receiving depression.

9. The rotation module of claim 8, wherein the buffer washer is made of plastic.

10. The rotation module of claim 8, wherein the buffer washer forms a plurality of micro-protrusions on a bottom surface of the buffer washer.

11. An electronic device comprising:
a main body;
a cover; and
a rotation module rotatably connecting the cover to the main body, the rotation module comprising:
a base comprising a resisting end and a connecting end opposite to the resisting end, a periphery of the resisting end forming a curved surface, the connecting end being fixed to main body; and
a rotation member rotatably positioned on the base, the rotation member comprising a bottom surface and a supporting surface opposite to the bottom surface, the cover being attached to the supporting surface, the rotation member defining a circular depression to receive the resisting end in the bottom surface of the rotation member; the depression having a circular slanted sidewall resisting the curved surface.

12. The electronic device of claim 11, wherein a periphery of the resisting end forms a ring-shaped protrusion; the curved surface is formed on an outer side of an end of the ring-shaped protrusion.

13. The electronic device of claim 12, wherein the ring-shaped protrusion is elastic.

14. The electronic device of claim 11, wherein a surface roughness of the curved surface is 3.2 μm to 12.8 μm, determined by the arithmetic average roughness (Ra).

15. The electronic device of claim 11, wherein a surface roughness of the slanted sidewall is 3.2 μm to 12.8 μm, determined by the arithmetic average roughness (Ra).

16. The electronic device of claim 11, further comprising a fixing member, wherein the base defines a through hole, the rotation member defines a locking hole, and the fixing member passes through the through hole and engages the locking hole.

17. The electronic device of claim 16, wherein the fixing member is a nut.

18. The electronic device of claim 11, further comprising a buffer washer, wherein the base defines a receiving depression in the bottom surface of the base, and a portion of the buffer washer is received in the receiving depression.

19. The electronic device of claim 18, wherein the buffer washer is made of plastic.

20. The electronic device of claim 18, wherein the buffer washer forms a plurality of micro-protrusions on a bottom surface of the buffer washer.
